(19) United States
(12) Patent Application Publication
(10) Pub. No.: US 2002/0135006 A1
(43) Pub. Date: Sep. 26, 2002

(54) Semiconductor device and method of manufacturing the same

(75) Inventor: Tomonori Okudaira, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Tokyo (JP)

(21) Appl. No.: 10/155,124

(22) Filed: May 28, 2002

Related U.S. Application Data
(62) Division of application No. 09/559,359, filed on Apr. 27, 2000.

(30) Foreign Application Priority Data
Nov. 8, 1999 (JP) P11-316597

(51) Int. Cl. H01L 27/108

(52) U.S. Cl. 257/296

(57) ABSTRACT

Provided are a semiconductor device which has a stacked capacitor and does not deteriorate characteristics even if hydrogen annealing is carried out to recover damages caused during a process and a method of manufacturing the semiconductor device. A plurality of storage node electrodes (SN2) are provided on a plug (6), respectively. A dielectric film (8) formed of BST is wholly provided to cover upper parts of the storage node electrodes (SN2). Then, a first conductive layer (91) formed of platinum is provided to cover the dielectric film (8). Furthermore, a second conductive layer (92) formed of TiN is provided to wholly cover the first conductive layer (91). Both the first and second conductive layers (91) and (92) constitute a counter electrode (90) to the storage node electrode.

### BACKGROUND OF THE INVENTION

1. Field of the Invention

The present invention relates to a semiconductor device and a method of manufacturing the semiconductor device, and more particularly to a semiconductor device capable of eliminating an influence caused by hydrogen annealing and a method of manufacturing the semiconductor device.

2. Description of the Background Art

In a semiconductor device, a transistor formed at the initial stage of a semiconductor manufacturing process is variously damaged at the step of forming an interlayer insulating film, the step of forming a wiring layer and the like which are to be carried out later. In a transistor made finer by an enhancement in the integration of a semiconductor device, in some cases, there is a problem in that a threshold voltage is caused to greatly fluctuate by these damages so as not to obtain such a characteristic as designed.

In order to recover the damages caused during the process, hydrogen annealing is carried out in the hydrogen atmosphere at the final stage of the process. In a semiconductor device such as a DRAM using, as a capacitor dielectric, a ferroelectric material, for example, PZT (lead zicronate titanate), or a high dielectric material, for example, BST (barium strontium titanate) or the like, there has been known that a deterioration in characteristics, for example, an increase in a leakage current is caused by the hydrogen annealing.

The deterioration in characteristics can be suppressed by adding oxygen to platinum (Pt) to be used as a capacitor electrode, for example, thereby giving the function of preventing the entry of hydrogen.

FIG. 16 shows a sectional structure of a memory cell portion of a DRAM having a stacked capacitor as an example of a DRAM having a comparatively low integration according to the prior art.

In FIG. 16, an interlayer insulating film 55 is formed on a silicon substrate 1, and a plurality of conductive plugs 56 reaching the silicon substrate 1 through the interlayer insulating film 55 are provided. The plug 56 is connected to an impurity layer such as a source-drain layer provided in a surface of the silicon substrate 1, which is not shown in the drawing.

One of ends of the plug 56 is connected to a barrier metal layer 573 which is selectively provided on the interlayer insulating film 55, and a bottom electrode 572 formed of platinum is provided on an upper part of a main surface of the barrier metal layer 573. A side wall spacer 571 is provided to cover side faces of the barrier metal layer 573 and the bottom electrode 572, and a storage node electrode SN1 of the stacked capacitor is constituted by the barrier metal layer 573, the bottom electrode 572 and the side wall spacer 571.

A plurality of storage node electrodes SN1 are provided on the plug 56, respectively. A dielectric film 58 formed of BST is wholly provided to cover upper parts of the storage node electrodes SN1, and a counter electrode (which will be hereinafter referred to as a cell plate) 59 to the storage node electrodes SN1 is wholly provided to cover the dielectric film 58. Thus, a stacked capacitor SC1 is constituted. The cell plate 59 is formed of platinum. By adding oxygen to the cell plate 59, hydrogen can be prevented from entering the structures of the cell plate 59 and others provided thereunder. Thus, the deterioration in characteristics can be prevented as described above.

In the case where the integration is low as shown in FIG. 16, the storage node SN1 has a small height and a high step coverage is obtained in the formation of the dielectric film 58 and the cell plate 59. However, when the integration is enhanced and the height of the storage node SN1 is increased, the step coverage of each of the dielectric film 58 and the cell plate 59 makes troubles.

FIG. 17 shows a sectional structure of a memory cell portion of a DRAM having a stacked capacitor SC2 as an example of a DRAM having a comparatively high integration according to the prior art.

In FIG. 17, an interlayer insulating film 5 is formed on a silicon substrate 1, and a plurality of conductive plugs 6 reaching the silicon substrate 1 through the interlayer insulating film 5 are provided. The plug 6 is connected to an impurity layer such as a source-drain layer provided in a surface of the silicon substrate 1, which is not shown in the drawing.

One of ends of the plug 6 is connected to a barrier metal layer 71 which is selectively provided on the interlayer insulating film 5, and a bottom electrode 72 formed of platinum is provided on an upper part of a main surface of the barrier metal layer 71. A side wall electrode 73 is provided to cover side faces of the barrier metal layer 71 and the bottom electrode 72, and a storage node electrode SN2 of the stacked capacitor is constituted by the barrier metal layer 71, the bottom electrode 72 and the side wall electrode 73.

The storage node electrodes SN2 are provided on the plug 6, respectively. A dielectric film 8 formed of BST is wholly provided to cover upper parts of the storage node electrodes SN2, and a counter electrode (which will be hereinafter referred to as a cell plate) 9 to the storage node electrodes SN2 is provided to cover the dielectric film 8. Thus, a stacked capacitor SC2 is constituted. The cell plate 9 is formed of platinum. By adding oxygen to the cell plate 9, hydrogen can be prevented from entering the structures of the cell plate 9 and others provided thereunder. However, a step coverage of the cell plate 9 makes troubles.

More specifically, it is difficult to form the platinum cell plate 9 by a CVD (chemical vapor deposition) method in respect of a technique and a cost. Therefore, the cell plate 9 is formed by a sputtering method. If a height of the storage node electrode SN2 is increased and a space between the storage node electrodes SN2 is reduced with an enhancement in the integration, a sufficient step coverage cannot be obtained in side face and bottom portions of the storage node electrode SN2 by the sputtering method. Depending on the circumstances, the cell plate 9 is discontinuously formed and the dielectric film 8 is exposed as shown in FIG. 17.

In such a state, hydrogen enters from the discontinuous portion of the cell plate 9 during hydrogen annealing. Consequently, the above-mentioned deterioration in the characteristics is caused.

### SUMMARY OF THE INVENTION

In order to solve the above-mentioned problems, it is an object of the present invention to provide a semiconductor device having a stacked capacitor which does not cause a deterioration in characteristics by hydrogen annealing to be carried out to recover damages generated during a process and a method of manufacturing the semiconductor device.

A first aspect of the present invention is directed to a semiconductor device comprising a plurality of capacitors, each of the capacitors being formed on an underlying layer and including a lower electrode, a dielectric film and an upper electrode, wherein the dielectric film is provided to cover an upper part and a side face of the lower electrode and the underlying layer formed between the capacitors, and the upper electrode has a first conductive layer covering at least the dielectric film of the upper part and side face of the lower electrode, and a second conductive layer covering an upper part and a side face of the first conductive layer and provided on an upper part of the dielectric film formed between the capacitors.

A second aspect of the present invention is directed to the semiconductor device, wherein the first conductive layer is formed by a sputtering method, and the second conductive layer is formed by a CVD method.

A third aspect of the present invention is directed to the semiconductor device, wherein the first conductive layer is formed of one of platinum group elements or an alloy containing at least one of the platinum group elements.

A fourth aspect of the present invention is directed to the semiconductor device, wherein the second conductive layer is formed of any of Ti, W, Ta and Ru as a main component.

A fifth aspect of the present invention is directed to a semiconductor device comprising a plurality of capacitors, each of the capacitors being formed on an underlying layer and including a lower electrode, a dielectric film and an upper electrode, wherein the dielectric film is provided to cover an upper part and a side face of the lower electrode and the underlying layer formed between the capacitors, and the upper electrode has a first conductive layer covering at least the dielectric film of the upper part and side face of the lower electrode, and a second conductive layer formed like a flat plate in contact with an upper part of the first conductive layer across all the capacitors.

A sixth aspect of the present invention is directed to the semiconductor device, wherein the first and second conductive layers are formed by a sputtering method.

A seventh aspect of the present invention is directed to the semiconductor device, wherein the first and second conductive layers are formed of one of platinum group elements or an alloy containing at least one of the platinum group elements.

An eighth aspect of the present invention is directed to a method of manufacturing a semiconductor device having first and second circuit portions which are formed on a semiconductor substrate and have structures different from each other, comprising the steps of (a) forming first and second portions of an underlying layer including a semiconductor element corresponding to portions to be the first and second circuit portions on the semiconductor substrate, (b) forming a plurality of capacitors including a lower electrode, a dielectric film and an upper electrode on the first portion of the underlying layer, (c) forming a first portion of an interlayer insulating film on the first portion of the underlying layer to cover the capacitors and forming a second portion of the interlayer insulating film on the second portion of the underlying layer, and (d) forming a metal layer on the first and second portions of the interlayer insulating film, the step (b) including the steps of forming the lower electrode on the first portion of the underlying layer, forming the dielectric film to cover an upper part and a side face of the lower electrode and the underlying layer formed between the capacitors, and forming the upper electrode to cover at least the dielectric film of the upper part and side face of the lower electrode, and the step (d) including the step of (d-1) forming the metal layer as a hydrogen block layer for wholly covering a formation region of the capacitors to prevent hydrogen from entering the capacitor side in the first circuit portion at the same step simultaneously with formation of the metal layer as a metal wiring layer in the second circuit portion.

A ninth aspect of the present invention is directed to the method of manufacturing a semiconductor device, wherein the step (d-1) has the step of forming the metal wiring layer and the hydrogen block layer by a sputtering method.

A tenth aspect of the present invention is directed to the method of manufacturing a semiconductor device, wherein the step (d-1) has the step of forming the metal wiring layer and the hydrogen block layer of Al or Cu.

An eleventh aspect of the present invention is directed to the method of manufacturing a semiconductor device, wherein the step (d-1) has the step of forming the metal wiring layer and the hydrogen block layer as a multilayer, one of the layers being formed of Al or Cu.

According to the first aspect of the present invention, the second conductive layer covers the upper part and side face of the first conducive layer and is provided on the upper part of the dielectric film between the capacitors. Therefore, it is also possible to cover the dielectric film which cannot be completely covered with the first conductive layer. Thus, hydrogen for hydrogen annealing to be carried out at the final stage of the process can be prevented from entering the structures of the upper electrode and others provided thereunder. Consequently, it is possible to prevent a deterioration in characteristics such as an increase in a leakage current from being caused.

According to the second aspect of the present invention, the first conductive layer is formed by the sputtering method and the second conductive layer is formed by the CVD method even if a step coverage makes troubles. Thus, it is also possible to obtain a high step coverage and to cover the dielectric film which cannot be completely covered with the first conductive layer. Moreover, the second conductive layer formed by the CVD method does not have a pin-hole or the like. Consequently, the passage of the hydrogen can be prevented reliably.

According to the third aspect of the present invention, the first conductive layer is formed of one of the platinum group elements or an alloy containing at least one of the platinum group elements. Therefore, the first conductive layer has small reducing properties. Also in the case where an oxide which is easily reduced is used for the dielectric film, the dielectric film is not reduced and keeps insulating properties. Consequently, the function of the capacitor is not damaged.

According to the fourth aspect of the present invention, in the case where the second conductive layer is formed of a nitride containing any of Ti, W, Ta and Ru as a main component and the first conductive layer is formed of one of the platinum group elements, both of them have smaller reactivity.

According to the fifth aspect of the present invention, the second conductive layer is provided like a flat plate in contact with the upper part of the first conductive layer across all the capacitors. Therefore, also in the case where the dielectric film cannot be completely covered with the first conductive layer, hydrogen for hydrogen annealing to be carried out at the final stage of the process can be prevented from entering the structures of the upper electrode and others provided thereunder and a deterioration in characteristics such as an increase in a leakage current can be prevented from being caused. Moreover, since the first conductive layer and the second conductive layer are provided in contact with each other, both electric potentials can be easily made common.

According to the sixth aspect of the present invention, the second conductive layer is formed by the sputtering method. Therefore, it is possible to use a metal film which is excellent in crack-resistant properties and is effective in the prevention of entry of the hydrogen.

According to the seventh aspect of the present invention, the first and second conductive layers are formed of one of the platinum group elements or an alloy containing at least one of the platinum group elements. Therefore, the first and second conductive layers have small reducing properties. Also in the case where an oxide which is easily reduced is used for the dielectric film, the dielectric film is not reduced and keeps insulating properties. Consequently, the function of the capacitor is not damaged.

According to the eighth aspect of the present invention, the hydrogen block layer for preventing the entry of the hydrogen is formed in the first circuit portion at the step of forming the metal wiring layer in the second circuit portion. Therefore, it is not necessary to provide a special-purpose step of forming a layer for preventing the entry of the hydrogen. Thus, an increase in a manufacturing cost can be suppressed.

According to the ninth aspect of the present invention, the hydrogen block layer is formed by the sputtering method. Consequently, it is possible to use a metal film which is excellent in crack-resistant properties and is effective in the prevention of the entry of the hydrogen.

According to the tenth aspect of the present invention, the metal wiring layer and the hydrogen block layer are formed of Al or Cu. Therefore, it is possible to obtain a low resistance of a wiring.

According to the eleventh aspect of the present invention, the metal wiring layer and the hydrogen block layer are formed as a multilayer and one of them is formed of Al or Cu. Therefore, it is possible to obtain a low resistance of a wiring and a structure having a metal film which is effective in the prevention of the entry of the hydrogen.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view illustrating a structure of a semiconductor device according to a first embodiment of the present invention;

FIGS. 2 to 7 are views illustrating the steps of manufacturing the semiconductor device according to the first embodiment of the present invention;

FIG. 8 is a view illustrating a structure of a semiconductor device according to a second embodiment of the present invention;

FIGS. 9 to 11 are views illustrating the steps of manufacturing the semiconductor device according to the second embodiment of the present invention;

FIGS. 12A and 12B are views illustrating a structure of a semiconductor device according to a third embodiment of the present invention;

FIGS. 13A and 13B, 14A and 14B, 15A and 15B are views illustrating the steps of manufacturing the semiconductor device according to the third embodiment of the present invention; and

FIGS. 16 and 17 are views illustrating a structure of a semiconductor device according to the prior art.

### DESCRIPTION OF THE PREFERRED EMBODIMENTS

<A. First Embodiment>

FIG. 1 shows a sectional structure of a memory cell portion of a DRAM 100 according to a first embodiment of the present invention.

<A-1. Structure of Device>

In FIG. 1, an interlayer insulating film 5 is formed on a silicon substrate 1, and a plurality of conductive plugs 6 reaching the silicon substrate 1 through the interlayer insulating film 5 are provided. The plug 6 is formed of polysilicon or titanium nitride (TiN).

A plurality of source-drain layers 2 of a MOS transistor and a plurality of element isolating films 3 for electrically isolating the MOS transistors are selectively provided in a surface of the silicon substrate 1. The plug 6 is connected to the source-drain layer 2.

Moreover, a gate electrode 41 is provided in the interlayer insulating film 5 corresponding to the silicon substrate 1 between the adjacent source-drain layers 2. A bit line 42 is provided corresponding to upper parts of the source-drain layers 2 to which the plug 6 is not connected. A bit line contact 43 for electrically connecting the bit line 42 to the source-drain layer 2 is provided therebetween.

The gate electrode 41 is also provided as a transfer gate above the element isolating film 3, and the bit line 42 is also provided above the element isolating film 3.

One of ends of the plug 6 is connected to a barrier metal layer 71 which is selectively provided on the interlayer insulating film 5, and a bottom electrode 72 formed of platinum is provided on an upper part of a main surface of the barrier metal layer 71. A side wall electrode 73 formed of platinum is provided to cover side faces of the barrier metal layer 71 and the bottom electrode 72, and a storage node electrode SN2 (a lower electrode) of a stacked capacitor is constituted by the barrier metal layer 71, the bottom electrode 72 and the side wall electrode 73.

The storage node electrodes SN2 are provided on the plug 6, respectively. A dielectric film 8 formed of BST is wholly provided to cover upper parts of the storage node electrodes SN2.

Then, a first conductive layer 91 formed of platinum is provided to cover the dielectric film 8. Furthermore, a second conductive layer 92 formed of TiN is provided to wholly cover the first conductive layer 91. Both the first and second conductive layers 91 and 92 constitute a counter electrode (which will be hereinafter referred to as a cell plate) 90 (an upper electrode) to the storage node electrode SN2.

The dielectric film 8 is interposed between the storage node electrode SN2 and the first conductive layer 91 which are formed of platinum. Although a dielectric substance such as BST which constitutes the dielectric film 8 is an oxide, it is easily reduced. If a material having great reducing properties comes in contact with the dielectric film 8, the dielectric film 8 is reduced so that the insulating properties thereof are damaged. If the dielectric film 8 acts as a capacitor portion, the function of a capacitor is lost. Therefore, the dielectric film 8 is interposed between the platinum layers having small reducing properties or the like.

The storage node electrode SN2, the dielectric film 8, the first conductive layer 91 and the second conductive layer 92 constitute a stacked capacitor SC10.

Then, an interlayer insulating film 10 is provided to cover the stacked capacitor SC10, a metal wiring layer 11 is provided on the interlayer insulating film 10, and a passivation film 12 is provided to cover the metal wiring layer 11. Thus, a DRAM 100 is constituted.

<A-2. Manufacturing Method>

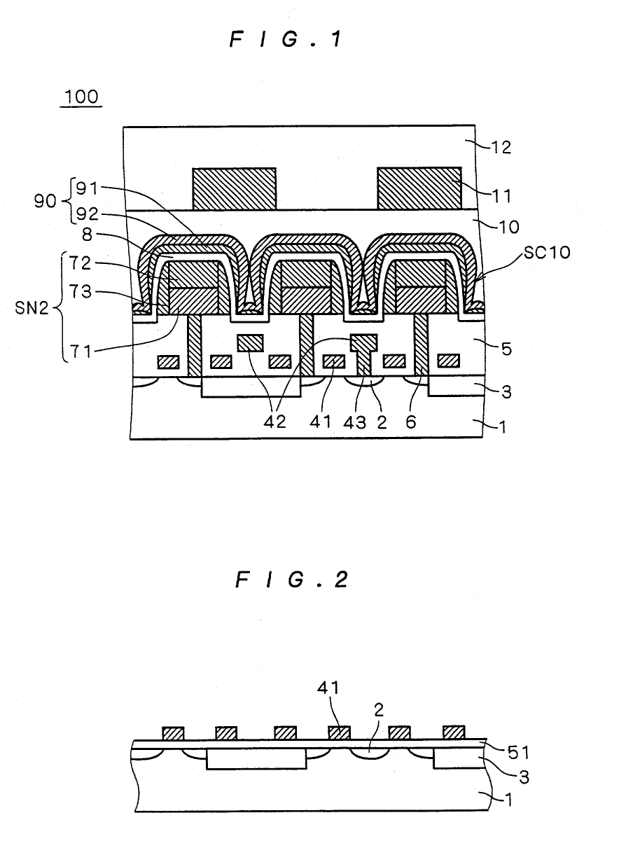

Next, a method of manufacturing the DRAM 100 will be described with reference to FIGS. 2 to 7.

First of all, a silicon substrate 1 is prepared and an element isolating film 3 made of an oxide film is selectively formed in a surface of the silicon substrate 1 at a step shown in FIG. 2.

Subsequently, an oxide film 51 to be a gate oxide film is wholly formed and a gate electrode 41 is selectively formed on the oxide film 51. At this time, the gate electrode 41 is also formed above the element isolating film 3 and acts as a transfer gate (a word line).

Then, an impurity ion is implanted into the silicon substrate 1 provided under the oxide film 51 by using the gate electrode 41 as a mask. Consequently, a source-drain layer 2 is selectively formed.

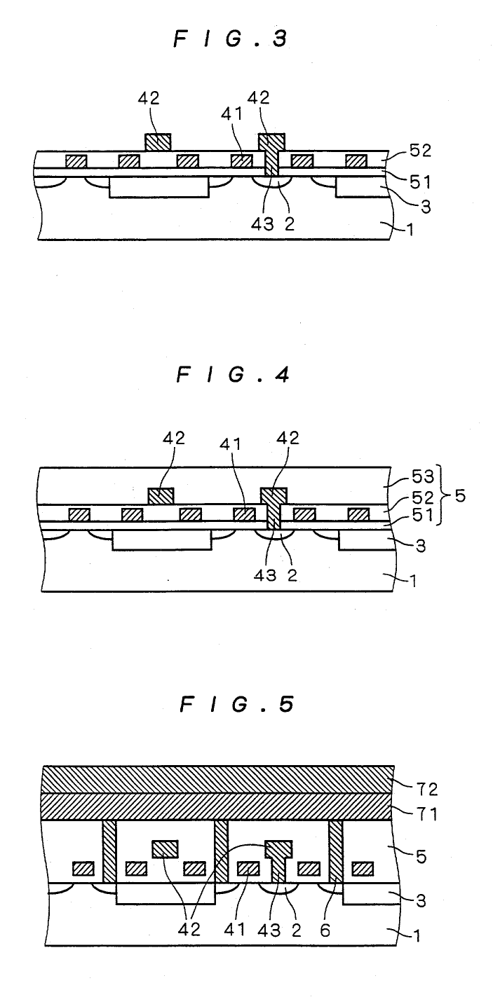

At a step shown in FIG. 3, next, an interlayer insulating film 52 made of an oxide film is formed to completely cover the gate electrode 41, and a contact hole reaching the source-drain layer 2 is selectively formed through the interlayer insulating film 52 and the oxide film 51 and is then filled with an electric conductor, thereby forming a bit line contact 43.

Thereafter, a bit line 42 is formed on the bit line contact 43. Consequently, the bit line 42 is electrically connected to the source-drain layer 2. The bit line 42 is also formed above the element isolating film 3.

At a step shown in FIG. 4, next, an interlayer insulating film 53 made of an oxide film is formed to completely cover the bit line 42. The oxide film 51 and the interlayer insulating films 52 and 53 are generally referred to as an interlayer insulating film 5 which will be described below.

At a step shown in FIG. 5, subsequently, a contact hole penetrating the interlayer insulating film 5 is formed in a conventional dry etching process to reach the source-drain layer 2 to which the bit line contact 43 is not connected. Then, a doped polysilicon layer is formed as an electric conductor, for example, on the interlayer insulating film 5 to fill in the contact hole. Thereafter, only the doped polysilicon layer provided on the interlayer insulating film 5 is removed by etch back, thereby forming a plug 6. The doped polysilicon layer to be formed on the interlayer insulating film. 5 has a thickness which is about 1.5 times as much as an opening radius of the contact hole.

The electric conductor constituting the plug 6 is not restricted to the doped polysilicon but may be a metal such as tungsten (W) or a conductive nitride such as TiN. Moreover, CMP (Chemical Mechanical Polishing) may be used for an etch back process.

Subsequently, a barrier metal layer 71 formed of TiN and a bottom electrode 72 formed of platinum, for example, are sequentially provided on the plug 6 by a sputtering method.

The barrier metal layer 71 and the bottom electrode 72 have thicknesses of approximately 100 nm and 50 nm, respectively.

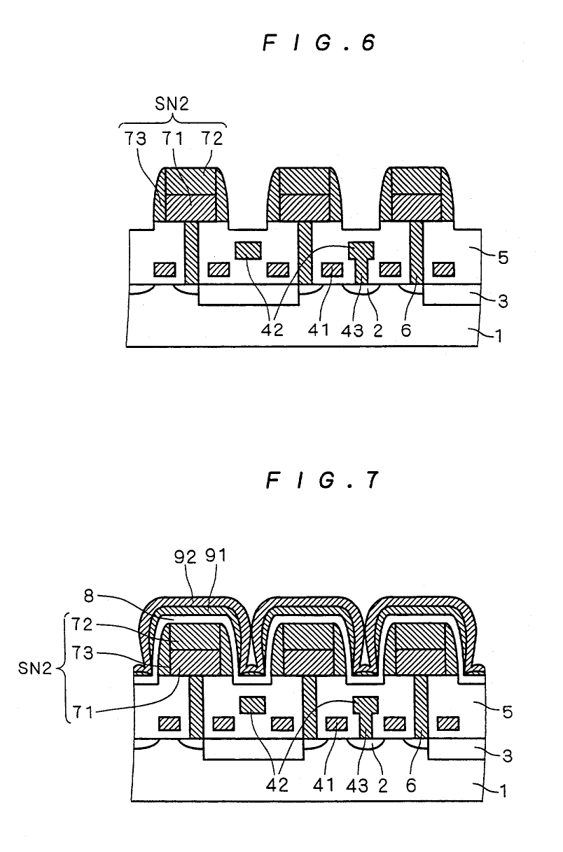

At a step shown in FIG. 6, next, the barrier metal layer 71 and the bottom electrode 72 are patterned into a predetermined pattern by a dry etching method. Then, a platinum layer is wholly formed in a thickness of approximately 50 nm by the sputtering method to cover the barrier metal layer 71 and the bottom electrode 72.

Then, the platinum layer is removed by anisotropic etching, thereby forming a side wall electrode 73 on side faces of the barrier metal layer 71 and the bottom electrode 72. Thus, a storage node electrode SN2 is obtained.

In some cases, an insulating material is used in place of the bottom electrode 72.

Moreover, a single layer structure having a thick ruthenium (Ru) layer may be used in place of a two-layer structure having the barrier metal layer 71 and the bottom electrode 72 of the storage node electrode SN2.

At a step shown in FIG. 7, next, a BST film and a platinum layer are sequentially provided by the sputtering method to wholly cover the storage node electrode SN2. Consequently, a dielectric film 8 and a first conductive layer 91 are formed. The dielectric film 8 and the first conductive layer 91 have thicknesses of approximately 60 nm and 100 nm, respectively.

The thicknesses of the dielectric film 8 and the first conductive layer 91 are not restricted to the above-mentioned thicknesses but may range from 30 nm to 60 nm and 30 nm to 100 nm, respectively.

Subsequently, a TiN layer having a thickness of approximately 10 nm is wholly formed by a CVD method to cover the first conductive layer 91 and is patterned into a predetermined pattern, thereby forming a second conductive layer 92. Thus, a stacked capacitor SC10 is constituted. A cell plate 90 is constituted by the first and second conductive layers 91 and 92. Moreover, a thickness of the second conductive layer 92 is not restricted to the above-mentioned thickness but may range from 5 nm to 50 nm.

The first conductive layer 91 to be formed by the sputtering method cannot have a sufficient step coverage in side face and bottom portions of the storage node electrode SN2 and is discontinuously provided, and a portion where the dielectric film 8 is exposed is generated in some cases. The second conductive layer 92 formed by the CVD method has a high step coverage, can cover side face and bottom portions of the first conductive layer 91 as well as an upper surface thereof, and furthermore, can completely cover the exposed dielectric film 8 in the stacked capacitor SC10.

While the example in which the BST film (high dielectric film) is used as the dielectric film 8 has been described, a PZT film (ferroelectric film) or a Ta₂O₅ film may be used.

Moreover, the bottom electrode 72, the side wall electrode 73 and the first conductive layer 91 are not restricted to platinum but may be formed of other platinum group elements (Ru, Rh, Pd, Os, Ir) or their alloys.

Furthermore, if the second conductive layer 92 is not restricted to the TiN film as a material thereof and is formed by the CVD method, it may be a layer made of WN (tungsten nitride) and TaN (tantalum nitride) themselves and containing silicon or aluminum (Al) or may be a PtO film or a Ru film which is formed by the CVD method.

The reason why the nitride is used as the second conductive layer 92 is that the reactivity of platinum and platinum group elements is small.

Subsequently, an interlayer insulating film 10 is formed to completely cover the stacked capacitor SC10. Then, a metal wiring layer 11 is formed on the interlayer insulating film 10. A passivation film 12 is formed to cover the metal wiring layer 11.

Finally, hydrogen annealing is carried out for 20 minutes in the hydrogen atmosphere at a temperature of 400° C. to recover damages caused during the process. Thus, the DRAM 100 shown in FIG. 1 is completely formed.

The second conductive layer 92 is connected to the upper wiring layer, for example, the metal wiring layer 11 through a contact portion (not shown) provided penetrating the interlayer insulating film 10. Thus, the cell plates 90 of the serial stacked capacitors SC10 have the same electric potential.

<A-3. Action and Effect>

As described above, the DRAM 100 comprises the second conductive layer 92 provided to cover the first conductive layer 91. Since the second conductive layer 92 is formed by the CVD method, it can have a high step coverage and can also cover the dielectric film 8 which cannot be completely covered with the first conductive layer 91. The hydrogen for the hydrogen annealing to be carried out at the final stage of the process can be prevented from entering the structures of the cell plate 90 and others provided thereunder. Thus, it is possible to prevent a deterioration in characteristics such as an increase in a leakage current from being caused.

The second conductive layer 92 to be formed by the CVD method does not have a pin-hole or the like and can reliably prevent the passage of the hydrogen.

<B. Second Embodiment>

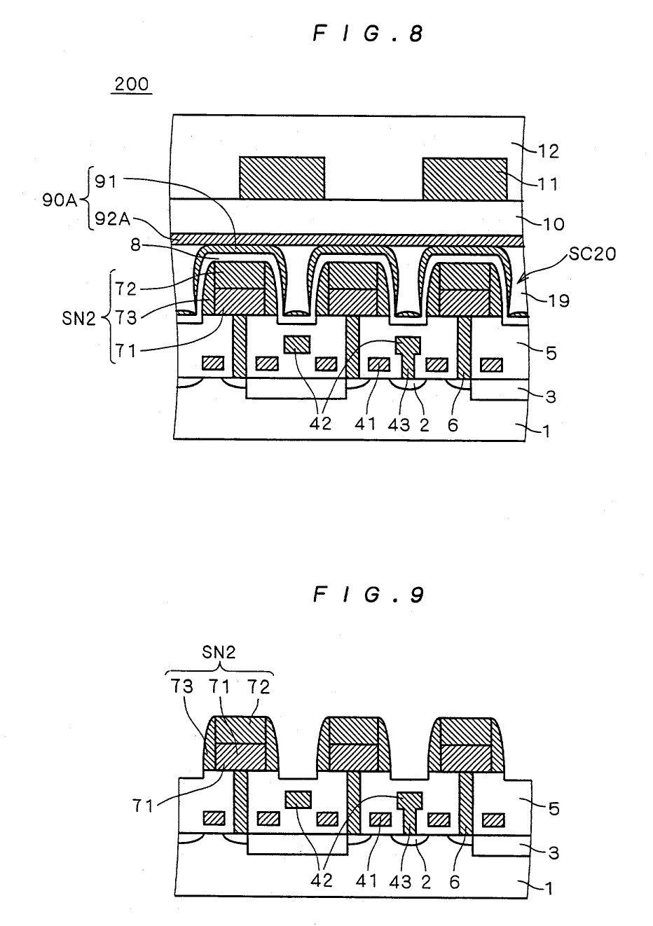

FIG. 8 shows a sectional structure of a memory cell portion of a DRAM 200 according to a second embodiment of the present invention. In FIG. 8, the same structures as in the DRAM 100 shown in FIG. 1 have the same reference numerals and their description will be omitted.

<B-1. Structure of Device>

In FIG. 8, a dielectric film 8 formed of BST is wholly provided to cover upper parts of a plurality of storage node electrodes SN2 (lower electrodes), and a first conductive layer 91 formed of platinum is provided to cover the dielectric film 8. An insulating film 19 is provided to fill in a portion between the storage node electrodes SN2 covered with the first conductive layer 91. Respective upper surfaces of the first conductive layers 91 covering the storage node electrodes SN2 are not covered with the insulating film 19 but are exposed, and a second conductive layer 92A formed of platinum is wholly provided in contact with the same upper surfaces. Both the first and second conductive layers 91 and 92A constitute a counter electrode (which will be hereinafter referred to as a cell plate) 90A (an upper electrode) to the storage node electrode SN2.

The storage node electrode SN2, the dielectric film 8, the first conductive layer 91 and the second conductive layer 92A constitute a stacked capacitor SC20.

An interlayer insulating film 10 is provided to cover the stacked capacitor SC20, a metal wiring layer 11 is provided on the interlayer insulating film 10, and a passivation film 12 is provided to cover the metal wiring layer 11. Thus, the DRAM 200 is constituted.

<B-2. Manufacturing Method>

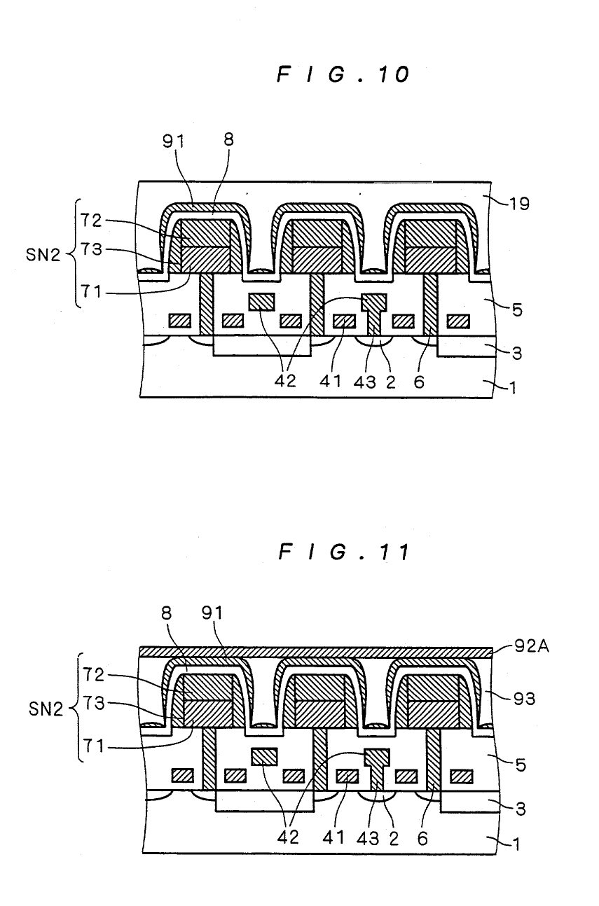

Next, a method of manufacturing the DRAM 200 will be described with reference to FIGS. 9 to 11.

Since the steps to be carried out until a structure shown in FIG. 9 is obtained are the same as the manufacturing steps described with reference to FIGS. 2 to 6, their description will be omitted.

At a step shown in FIG. 9, a barrier metal layer 71 and a bottom electrode 72 are patterned into a predetermined pattern by a dry etching method, and a platinum layer is then formed in a thickness of 50 nm by a sputtering method to wholly cover the barrier metal layer 71 and the bottom electrode 72.

Thereafter, the platinum layer is removed by anisotropic etching, thereby forming a side wall electrode 73 on side faces of the barrier metal layer 71 and the bottom electrode 72. Thus, a storage node electrode SN2 is obtained.

At a step shown in FIG. 10, next, a BST film and a platinum layer are sequentially provided by a sputtering method to wholly cover the storage node electrode SN2. Consequently, a dielectric film 8 and a first conductive layer 91 are formed. The dielectric film 8 and the first conductive layer 91 have thicknesses of approximately 60 nm and 100 nm, respectively.

Subsequently, an insulating film 19 having a thickness of approximately 100 nm is wholly formed to cover the first conductive layer 91, thereby completely filling in a portion provided between the storage node electrodes SN2 covered with the first conductive layer 91.

The thicknesses of the dielectric film 8 and the first conductive layer 91 are not restricted to the above-mentioned thicknesses but may range from 30 nm to 60 nm and 30 nm to 100 nm, respectively.

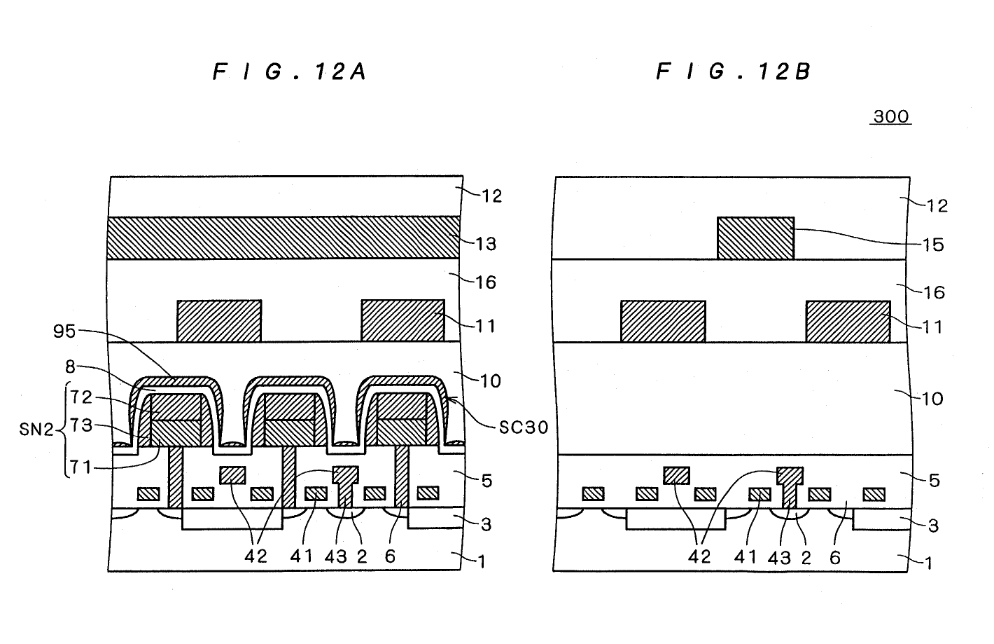

At a step shown in FIG. 11, next, the insulating film 19 is etched back and flattened until respective upper surfaces of the first conductive layers 91 covering a plurality of storage node electrodes SN2 are exposed.

Subsequently, a platinum layer having a thickness of 100 nm is wholly formed by a sputtering method and is patterned into a predetermined pattern, thereby forming a second conductive layer 92A in contact with the respective upper surfaces of the first conductive layers 91. Thus, a stacked capacitor SC20 is constituted. A cell plate 90A is constituted by the first and second conductive layers 91 and 92A. Moreover, a thickness of the second conductive layer 92A is not restricted to the above-mentioned thickness but may range from 15 nm to 100 nm.

Then, an interlayer insulating film 10 is formed to completely cover the stacked capacitor SC20. Then, a metal wiring layer 11 is formed on the interlayer insulating film 10. A passivation film 12 is formed to cover the metal wiring layer 11.

Finally, hydrogen annealing is carried out for 20 minutes in the hydrogen atmosphere at a temperature of 400° C. to recover damages caused during the process. Thus, the DRAM 200 shown in FIG. 8 is completely formed.

<B-3. Action and Effect>

As described above, the second conductive layer 92A formed of platinum is wholly provided in contact with the respective upper surfaces of the first conductive layers 91 covering the storage node electrodes SN2 in the DRAM 200. Therefore, also in the case where the dielectric film 8 cannot be completely covered with the first conductive layer 91, the hydrogen for the hydrogen annealing to be carried out at the final stage of the process can be prevented from entering the structures of the cell plate 90A and others provided thereunder. Thus, it is possible to prevent a deterioration in characteristics such as an increase in a leakage current from being caused.

Since the second conductive layer 92A is wholly provided in contact with the respective upper surfaces of the first conductive layers 91, both the second and first conductive layers 92A and 91 have the same electric potential. The second conductive layer 92A is connected to the upper wiring layer, for example, the metal wiring layer 11 through a contact portion (not shown) provided penetrating the interlayer insulating film 10. Thus, the cell plates 90A of the serial stacked capacitors SC20 can have the same electric potential.

Moreover, the second conductive layer 92A is formed like a flat plate. Therefore, it is not necessary to take a step coverage into consideration and film formation can be carried out by the sputtering method. Therefore, it is possible to use platinum and other metallic materials which are excellent in crack-resistant properties and are effective in the prevention of the entry of hydrogen.

<C. Third Embodiment>

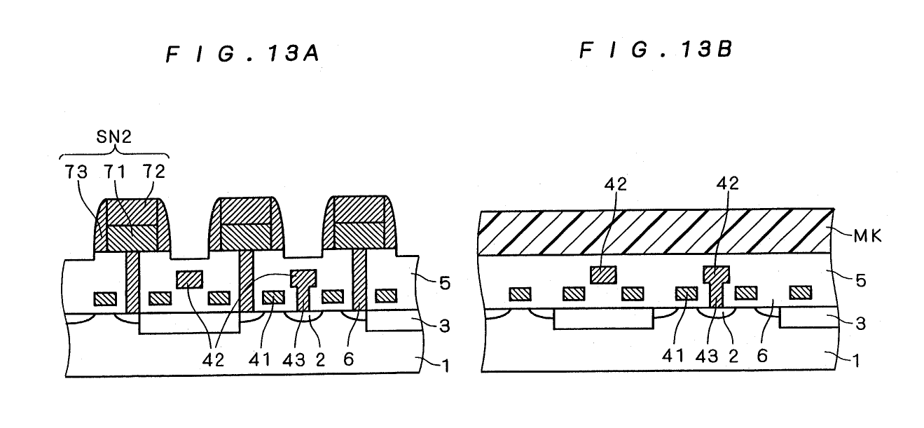

FIGS. 12A and 12B show sectional structures of a memory cell portion (a first circuit portion) and a peripheral circuit portion (a second circuit portion) of a DRAM 300 according to a third embodiment of the present invention. In FIG. 8, the same structures as in the DRAM 100 shown in FIG. 1 have the same reference numerals and their description will be omitted.

In FIG. 8, moreover, a structure including the interlayer insulating film 5 and the semiconductor element in the interlayer insulating film 5 will generally be referred to as an underlying layer. In some cases, underlying layers in the memory cell portion and the peripheral circuit portion are referred to as first and second portions of the underlying layer respectively in order to distinguish them from each other.

The foregoing is the same as in an interlayer insulating film other than the interlayer insulating film 5. In some cases, the interlayer insulating films in the memory cell portion and the peripheral circuit portion are referred to as first and second portions of the interlayer insulating film, respectively.

<C-1. Structure of Device>

In FIG. 12A showing the memory cell portion, a dielectric film 8 formed of BST is wholly provided to cover upper parts of a plurality of storage node electrodes SN2 (lower electrodes), and a cell plate 95 (an upper electrode) formed of platinum is provided to cover the dielectric film 8. Thus, a stacked capacitor SC30 is constituted. An interlayer insulating film 10 is provided to completely cover the storage node electrode SN2 covered with the cell plate 95.

Then, a metal wiring layer 11 is provided on the interlayer insulating film 10, an interlayer insulating film 16 is provided to cover the metal wiring layer 11, a hydrogen block layer 13 is provided on the interlayer insulating film 16, and a passivation film 12 is provided to cover the hydrogen block layer 13.

In FIG. 12B showing the peripheral circuit portion, a structure of a surface of a silicon substrate 1 and that of an interlayer insulating film 5 covering the silicon substrate 1 are basically identical to the structures shown in FIG. 12A. In a peripheral circuit, however, a stacked capacitor is not provided on the interlayer insulating film 5. Therefore, a plug 6 and the like are not provided.

An interlayer insulating film 10 is provided on the interlayer insulating film 5, a metal wiring layer 11 is provided on the interlayer insulating film 10, an interlayer insulating film 16 is provided to cover the metal wiring layer 11, a metal wiring layer 15 is provided on the interlayer insulating film 16, and a passivation film 12 is provided to cover the metal wiring layer 15.

<C-2. Manufacturing Method>

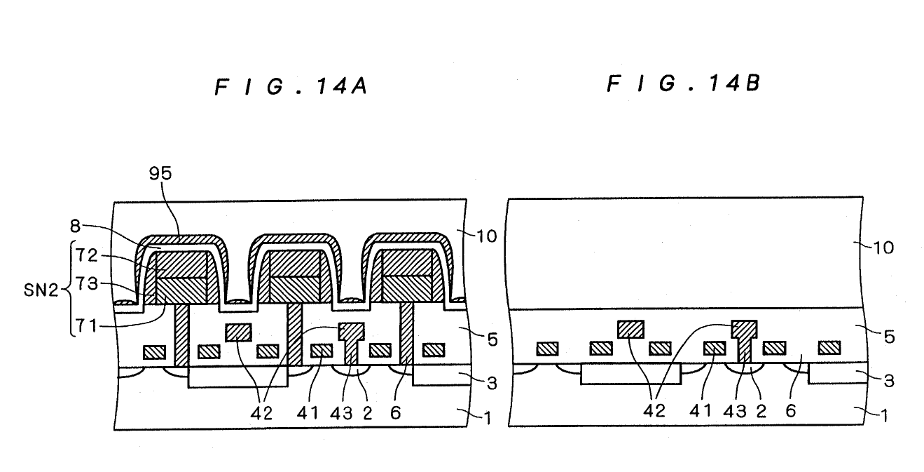

Next, a method of manufacturing the DRAM 300 will be described with reference to FIGS. 13A and 13B to FIGS. 15A and 15B.

Since the steps to be carried out until structures shown in FIGS. 13A and 13B are obtained are the same as the manufacturing steps described with reference to FIGS. 2 to 6, their description will be omitted.

In the memory cell portion, at a step shown in FIG. 13A, a barrier metal layer 71 and a bottom electrode 72 which are provided on an interlayer insulating film 5 (a first portion of an underlying layer) are patterned into a predetermined pattern by a dry etching method, and a platinum layer is then formed in a thickness of 50 nm by a sputtering method to wholly cover the barrier metal layer 71 and the bottom electrode 72.

Thereafter, the platinum layer is removed by anisotropic etching, thereby forming a side wall electrode 73 on side faces of the barrier metal layer 71 and the bottom electrode 72. Thus, a storage node electrode SN2 is obtained.

In the peripheral circuit portion, as shown in FIG. 13B, a mask MK is formed on the interlayer insulating film 5 (a second portion of the underlying layer). Consequently, an unnecessary structure such as the storage node electrode SN2 is not formed.

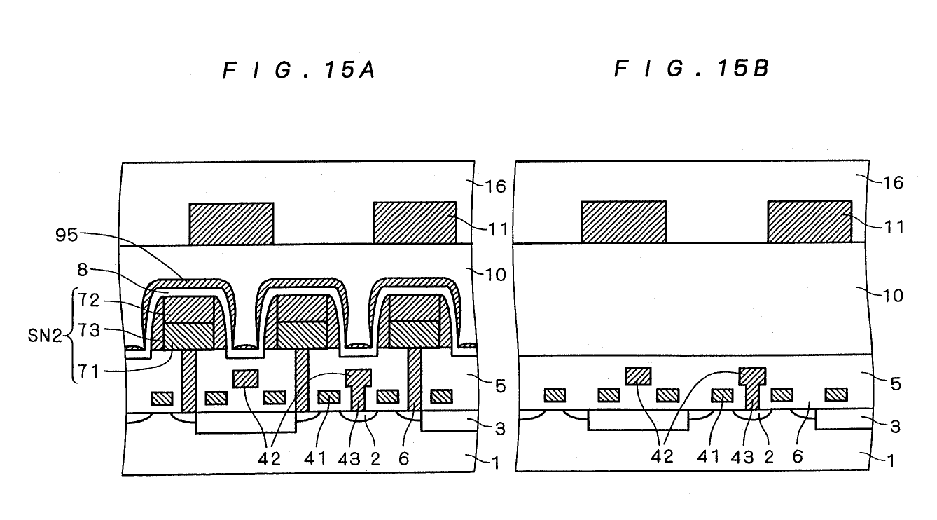

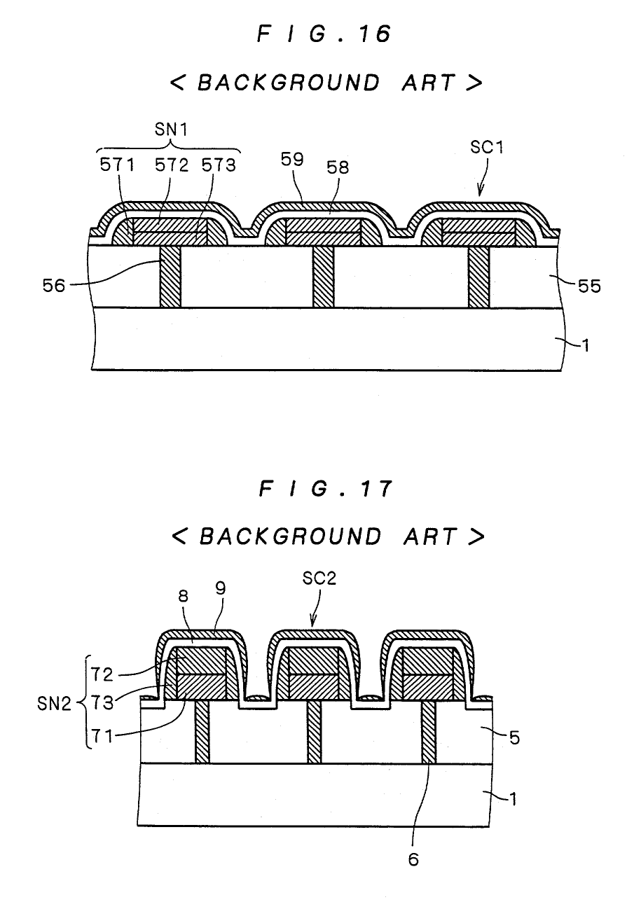

In the memory cell portion, at a step shown in FIG. 14A, a BST film and a platinum layer are sequentially provided by a sputtering method to wholly cover the storage node electrode SN2, thereby forming a dielectric film 8 and a cell plate 95. The dielectric film 8 and the cell plate 95 have thicknesses of approximately 60 nm and 100 nm, respectively.

The thicknesses of the dielectric film 8 and the cell plate 95 are not restricted to the above-mentioned thicknesses but may range from 30 nm to 60 nm and 30 nm to 100 nm, respectively.

Subsequently, an interlayer insulating film 10 (a first portion of the interlayer insulating film) is formed to completely cover the storage node electrode SN2 covered with the cell plate 95.

In the peripheral circuit portion, the mask MK formed on the interlayer insulating film 5 is removed corresponding to the formation of the interlayer insulating film 10 (the first portion of the interlayer insulating film) in the memory cell portion. Thus, an interlayer insulating film 10 is formed as shown in FIG. 14B.

In the memory cell portion and the peripheral circuit portion, next, a metal wiring layer 11 is formed on the interlayer insulating film 10 and an interlayer insulating film 16 is formed to cover the metal wiring layer 11 as shown in FIGS. 15A and 15B.

Subsequently, a metal layer having a thickness of approximately 100 nm is formed, by a sputtering method, on the interlayer insulating film 16 in the memory cell portion and the peripheral circuit portion. The metal layer is formed of a wiring material such as aluminum.

Then, the metal layer is patterned into a predetermined pattern to form a hydrogen block layer 13 in the memory cell portion and a metal wiring layer 15 in the peripheral circuit portion.

Then, a passivation film 12 is formed to cover the hydrogen block layer 13 and the metal wiring layer 15.

Finally, hydrogen annealing is carried out for 20 minutes in the hydrogen atmosphere at a temperature of 400° C. to recover damages caused during the process. Thus, the DRAM 300 shown in FIGS. 12A and 12B is completely formed.

The cell plate 95 is connected to the upper wiring layer, for example, the metal wiring layer 11 through a contact portion (not shown) provided penetrating the interlayer insulating film 10. Thus, the cell plates 95 of the serial stacked capacitors SC30 have the same electric potential.

<C-3. Action and Effect>

As described above, the hydrogen block layer 13 is provided, by the sputtering method, in the layer for forming the wiring of the memory cell portion in the DRAM 300. Therefore, also in the case where the dielectric film 8 cannot be completely covered with the cell plate 95, the hydrogen for the hydrogen annealing to be carried out at the final stage of the process can be prevented from entering the structures of the hydrogen block layer 13 and others provided thereunder. Thus, it is possible to prevent a deterioration in characteristics such as an increase in a leakage current from being caused.

In similarity to the relationship between the hydrogen block layer 13 in the memory cell portion and the metal wiring layer 15 in the peripheral circuit portion, the layer for preventing the hydrogen from entering is formed in the memory cell portion at the step of forming the metal wiring layer in the peripheral circuit portion. Therefore, it is not necessary to provide a special-purpose step of forming a layer for preventing the entry of the hydrogen. Consequently, an increase in a manufacturing cost can be suppressed.

In the DRAM 300 shown in FIGS. 12A and 12B, the metal wiring layer has one layer in the memory cell portion and two layers in the peripheral circuit portion, and the hydrogen block layer 13 is provided as an uppermost layer. In a memory having a logic circuit mounted thereon or the like, the wiring layer sometimes has three to six layers. Also in this case, an increase in a manufacturing cost can be suppressed by forming the hydrogen block layer in the memory cell portion simultaneously with the step of forming the wiring layer in the peripheral circuit portion. In this case, moreover, it is not necessary to form the hydrogen block layer as the uppermost layer.

Furthermore, while the aluminum formed by the sputtering method has been used as the hydrogen block layer 13 in the DRAM 300, the forming method is not restricted to the sputtering method but may be a CVD method or the like. In the case where the formation is carried out by the sputtering method, it is possible to obtain a hydrogen block layer which is excellent in crack-resistant properties.

While the hydrogen block layer 13 has the single layer structure of aluminum in the DRAM 300, it may be formed to have a multilayer structure.

In that case, it is desirable that the function of the wiring layer in the peripheral circuit portion as well as the prevention of the entry of hydrogen should be taken into consideration and at least one layer should be formed of aluminum or copper (Cu) in order to reduce a wiring resistance.

While the invention has been described in detail, the foregoing description is in all aspects illustrative and not restrictive. It is understood that numerous other modifications and variations can be devised without departing from the scope of the invention.

What is claimed is:

1. A semiconductor device comprising a plurality of capacitors, each of said capacitors being formed on an underlying layer and including a lower electrode, a dielectric film and an upper electrode,
wherein said dielectric film is provided to cover an upper part and a side face of said lower electrode and said underlying layer formed between said capacitors, and
said upper electrode has:
a first conductive layer covering at least said dielectric film of said upper part and side face of said lower electrode; and
a second conductive layer covering an upper part and a side face of said first conductive layer and provided on an upper part of said dielectric film formed between said capacitors.

2. The semiconductor device according to claim 1, wherein said first conductive layer is formed by a sputtering method, and
said second conductive layer is formed by a CVD method.

3. The semiconductor device according to claim 2, wherein said first conductive layer is formed of one of platinum group elements or an alloy containing at least one of said platinum group elements.

4. The semiconductor device according to claim 2, wherein said second conductive layer is formed of any of Ti, W, Ta and Ru as a main component.

5. A semiconductor device comprising a plurality of capacitors, each of said capacitors being formed on an underlying layer and including a lower electrode, a dielectric film and an upper electrode,
wherein said dielectric film is provided to cover an upper part and a side face of said lower electrode and said underlying layer formed between said capacitors, and
said upper electrode has:
a first conductive layer covering at least said dielectric film of said upper part and side face of said lower electrode; and
a second conductive layer formed like a flat plate in contact with an upper part of said first conductive layer across all said capacitors.

6. The semiconductor device according to claim 5, wherein said first and second conductive layers are formed by a sputtering method.

7. The semiconductor device according to claim 6, wherein said first and second conductive layers are formed of one of platinum group elements or an alloy containing at least one of said platinum group elements.

8. A method of manufacturing a semiconductor device having first and second circuit portions which are formed on a semiconductor substrate and have structures different from each other, comprising the steps of:
(a) forming first and second portions of an underlying layer including a semiconductor element corresponding to portions to be said first and second circuit portions on said semiconductor substrate;
(b) forming a plurality of capacitors including a lower electrode, a dielectric film and an upper electrode on said first portion of said underlying layer;
(c) forming a first portion of an interlayer insulating film on said first portion of said underlying layer to cover said capacitors and forming a second portion of said interlayer insulating film on said second portion of said underlying layer; and
(d) forming a metal layer on said first and second portions of said interlayer insulating film,
said step (b) including the steps of:
forming said lower electrode on said first portion of said underlying layer;
forming said dielectric film to cover an upper part and a side face of said lower electrode and said underlying layer formed between said capacitors; and
forming said upper electrode to cover at least said dielectric film of said upper part and side face of said lower electrode, and
said step (d) including the step of:
(d-1) forming said metal layer as a hydrogen block layer for wholly covering a formation region of said capacitors to prevent hydrogen from entering said capacitor side in said first circuit portion at the same step simultaneously with formation of said metal layer as a metal wiring layer in said second circuit portion.

9. The method of manufacturing a semiconductor device according to claim 8, wherein said step (d-1) has the step of forming said metal wiring layer and said hydrogen block layer by a sputtering method.

10. The method of manufacturing a semiconductor device according to claim 8, wherein said step (d-1) has the step of forming said metal wiring layer and said hydrogen block layer of Al or Cu.

11. The method of manufacturing a semiconductor device according to claim 8, wherein said step (d-1) has the step of forming said metal wiring layer and said hydrogen block layer as a multilayer, one of said layers being formed of Al or Cu.
